(19) United States
(12) Patent Application Publication
(10) Pub. No.: US 2026/0155809 A1
(43) Pub. Date: Jun. 4, 2026

(54) DELAY CIRCUITRY

(71) Applicant: Arm Limited, Cambridge (GB)

(72) Inventors: Steve DAO, Austin, TX (US); Subramanya Ravindra SHINDAGIKAR, Bangalore (IN)

(21) Appl. No.: 18/967,866

(22) Filed: Dec. 4, 2024

(51) Int. Cl. H03K 3/037; H03K 5/135; H03K 5/1534

(52) U.S. Cl. CPC H03K 3/0372; H03K 5/135; H03K 5/1534

(57) ABSTRACT

There is described delay circuitry including: a pulse generator to generate a pulse responsive to receiving an input signal edge and to buffer and invert the input signal edge; and a signal output element to receive the pulse and the buffered and inverted signal edge from the pulse generator and to generate a delayed signal edge responsive to a trailing edge of the pulse and based on the buffered and inverted signal edge. In addition, there is described delay circuitry including: a buffer-inverter unit to receive, buffer and invert an input signal and to generate a delayed output signal, the buffer-inverter unit including a signal-controlled gate to invert the input signal arranged in series with a mode-controlled gate to pass the input signal. Finally, there is described apparatus including the delay circuitry and a flip flop.

### FIELD OF THE INVENTION

The present techniques relate to delay circuitry, and in particular, to clock delay circuitry for soft edge flip flops.

### BACKGROUND OF THE INVENTION

Flip flops are fundamental building blocks of integrated circuits and are widely used in digital circuit design. Flip flops are data storage elements each configured to store a single bit of data. Edge-triggered flip-flops are controllable by a control signal, typically a clock signal, to trigger a state change between one of two stable states on a control signal edge.

Some flip flops implementations may experience performance issues, for example, non-conformity with timing parameters leading to a risk of the flip flop entering a metastable state.

Existing mitigations address such performance issues by relying on soft edge flip flops, which comprise a window of transparency, or ‘softness’, around a control signal edge during which both the master and slave latches of the flip flop are transparent. In this way, the softness allows time to be ‘borrowed’ from a future clock period to extend the present clock period.

The present techniques relate to efficient provision of control signal edges for soft edge flip flops.

### SUMMARY OF THE INVENTION

At its most general, the present invention provides delay circuitry suitable to delay a signal, such as a clock edge, for subsequent use in any further circuitry, for example, a flip flop. In some embodiments, the delay circuitry comprises a plurality of buffer-inverter units configured to dissipate less power for a given delay effect than the delay circuitry of the prior art. In some embodiments, the delay circuitry comprises a pulse generator configured to generate a pulse to delay propagation of a signal edge through the delay circuitry until the pulse has elapsed, i.e., until a trailing edge of the pulse is triggered.

According to a first approach of present techniques, there is provided delay circuitry comprising: a pulse generator to generate a pulse responsive to receiving an input signal edge and to buffer and invert the input signal edge to generate a buffered and inverted signal edge; and a signal output element to receive the pulse and the buffered and inverted signal edge from the pulse generator and to generate a delayed signal edge responsive to a trailing edge of the pulse and based on the buffered and inverted signal edge.

In some implementations, the pulse generator comprises: a delay element to receive the input signal edge and generate the buffered and inverted signal edge; and a pulse output element to receive the input signal edge and the buffered and inverted signal edge and generate the pulse.

In some implementations, the pulse output element comprises logic to: switch, responsive to receiving the input signal edge, to trigger a leading edge of the pulse; and switch, responsive to receiving the buffered and inverted signal edge, to trigger a trailing edge of the pulse; to provide a delay effect corresponding to a duration of switching the delay element, switching the pulse output element and switching the signal output element sequentially.

The logic configured to switch may comprise logic gates formed of transistors. The delay effect may be an amount or duration of delay achieved by the circuitry.

In some implementations, the pulse output element comprises an AND gate and the signal output element comprises a NOR gate; or wherein the pulse output element comprises an OR gate and the signal output element comprises a NAND gate.

In some implementations, the delay element comprises a logic inverting element to buffer and invert the input signal edge.

In some implementations, the delay element comprises a plurality of logic inverting elements each configured to buffer and invert the input signal edge. In implementations where the pulse output element comprises an AND gate and the signal output element comprises a NOR gate, the delay element may comprise an odd number of logic inverting elements. In implementations where the pulse output element comprises an OR gate and the signal output element comprises a NAND gate, the delay element may comprise an even number of logic inverting elements. In this way, the delay element may always output a buffered and inverted signal edge.

In some implementations, the delay element further comprises a transmission gate.

In some implementations, the delay element comprises a combinatorial logic element to receive the input signal edge and at least one other signal. In some implementations, the combinatorial logic element may be configured to review three, four or even more than four input signals.

In some implementations, the combinatorial logic element comprises an OR-AND-invert gate or an AND-OR-invert gate.

In some implementations, the combinatorial logic element of the delay element is configured to receive a partially buffered signal edge. In some implementations, the combinatorial logic element may receive the partially buffered signal edge as feedback from downstream circuit elements.

In some implementations, the combinatorial logic element of the delay element is configured to receive a control signal to adjust a mode of operation of the delay circuitry.

In some implementations, the combinatorial logic element of the delay element is configured to receive the pulse via a feedback path arranged to connect an output of the pulse output element to an input of the combinatorial logic element; and the delay element is configured to output the buffered and inverted signal edge responsive to receiving the pulse. For example, the delay element may be configured to output the buffered and inverted signal edge responsive to receiving the leading edge of the pulse.

In some implementations, the pulse output element comprises logic to: switch, responsive to receiving the input signal edge, to trigger a leading edge of the pulse; and switch, responsive to receiving the buffered and inverted signal edge, to trigger a trailing edge of the pulse; to provide a delay effect corresponding to a duration of switching the pulse output element a first time, switching the delay element, switching the pulse output element a second time and switching the signal output element sequentially.

In some implementations, the input signal edge is an input clock edge. In other words, in some implementations, the input signal is a clock signal and the delayed signal is a delayed clock signal.

In some implementations, the signal output element is configured to generate a delayed signal having a duty cycle that is substantially identical to a duty cycle of the input signal. For example, where the input signal is a clock signal and the delayed signal is a delayed clock signal, the duty cycle of the delayed clock signal may permit, i.e., not preclude, the delayed clock signal to be used in place of a clock signal in any further circuitry, for example, a flip flop.

In some implementations, the signal output element is configured to receive a control signal to adjust a mode of operation of the delay circuitry.

According to a further approach of present techniques, there is provided delay circuitry comprising: a buffer-inverter unit to receive, buffer and invert an input signal and to generate a delayed output signal, the buffer-inverter unit comprising a first logic gate arranged in series with a second logic gate; wherein one of the first logic gate and the second logic gate is a signal-controlled gate configured to invert the input signal and the other of the first logic gate and the second logic gate is a mode-controlled gate configured to pass the input signal; wherein switching of the signal-controlled gate is configured to be controlled by the input signal; and wherein switching of the mode-controlled gate is configured to be controlled by a control signal indicative of a mode of circuit operation such that switching of the mode-controlled gate is independent of the input signal.

In some implementations, the mode-controlled gate comprises a plurality of mode-controlled gate stages arranged in series.

According to a further approach of present techniques, there is provided an apparatus comprising the delay circuitry of any previous approach and a flip flop to store a data signal responsive to receiving the delayed signal edge from the delay circuitry.

According to a further approach of present techniques, there is provided delay circuitry comprising: a pulse generator to generate a pulse responsive to receiving an input signal edge and to buffer and invert the input signal edge to generate a buffered and inverted signal edge; and a signal output element to receive the pulse and the buffered and inverted signal edge from the pulse generator and to generate a delayed signal edge responsive to a trailing edge of the pulse and based on the buffered and inverted signal edge; the pulse generator comprising: a buffer-inverter unit to receive, buffer and invert an input signal and to generate a delayed output signal, the buffer-inverter unit comprising a first logic gate arranged in series with a second logic gate; one of the first logic gate and the second logic gate being a signal-controlled gate to invert the input signal and the other of the first logic gate and the second logic gate being a mode-controlled gate to pass the input signal; wherein switching of the signal-controlled gate is configured to be controlled by the input signal; and wherein switching of the mode-controlled gate is configured to be controlled by a control signal indicative of a mode of circuit operation such that switching of the mode-controlled gate is independent of the input signal.

### BRIEF DESCRIPTION OF THE DRAWINGS

Implementations of the present techniques will now be described by way of example only and with reference to the accompanying drawings, in which:

FIG. 1 shows a circuit diagram of delay circuitry according to the prior art;

FIG. 2 shows a circuit diagram of delay circuitry according to an approach of present techniques;

FIGS. 3A-3C show block diagrams of delay circuitry according to an approach of present techniques;

FIGS. 4A-4C show logic diagrams of delay circuitry according to an approach of present techniques;

FIG. 5 shows a schematic timing diagram for the delay circuitry of FIG. 4B;

FIG. 6 shows a circuit diagram of the delay circuitry of FIG. 4B; and

FIG. 7 shows a circuit diagram of an apparatus according to an approach of present techniques.

### DETAILED DESCRIPTION

Soft edge flops enable processors to operate at increased processing speeds, or clock frequencies, while maintaining performance objectives by permitting limited time borrowing. However, conventional soft edge flops are inefficient in terms of both power consumption and area. Present techniques disclose delay circuitry that significantly reduces power and area requirement while maintaining performance.

Soft edge flip flops provide a window of transparency, or ‘softness’, around a control signal edge during which both the master and slave latches of the flip flop are transparent. In this way, the softness allows time to be ‘borrowed’ from a future clock period to extend the present clock period.

To achieve this ‘softness’, delay circuitry is required to provide the flip flop with a delayed clock signal, as well as a non-delayed clock signal. By providing a delayed clock signal to the master latch of the flip flop and a non-delayed clock signal to the slave latch of the flip flop, an overlap, or window, is provided during which both the master and slave latches are transparent such that data may pass through both latches.

Conventional delay circuity is a significant source of soft edge flip flop inefficiency;

often comprises a relatively large number of clock connected transistors all switching at least clock edge leading to high dynamic power dissipation and low efficiency of delay effect achieved per device or for a given power or area.

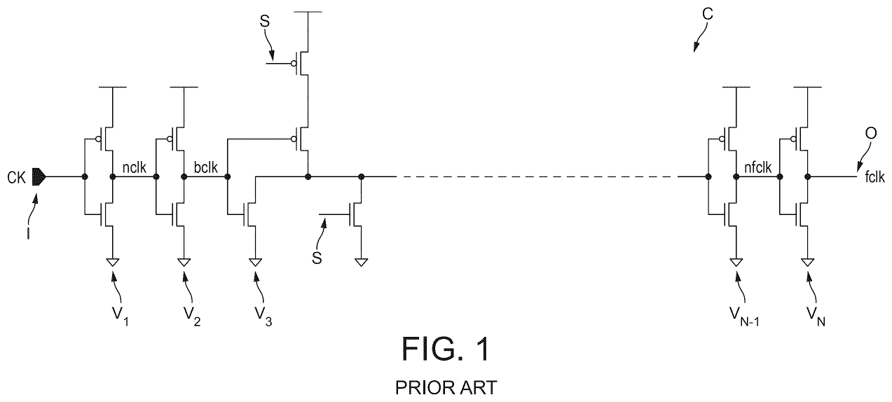

With reference to FIG. 1, there is illustrated delay circuitry C according to the prior art. The delay circuitry C comprises an input I configured to receive a clock signal, CK, and an output O configured to output a delayed clock signal, fclk. The delay circuitry C comprises an N stage delay line, each stage comprising an inverter V₁-V_{N}. A clock edge arriving at an inverter causes the inverter to switch. Each switching event has a known duration. By arranging N (e.g., 16) inverter stages in series, a delay corresponding to N times the known duration of switching one inverter V may be achieved by the delay circuitry C.

A scan enable control signal S is provided to the delay circuitry C at the third stage, V₃, to provide a delay line bypass during scanning. During scanning, a minimally delayed clock signal, bclk, output from the second inverter stage, V₂, is taken as the output of the delay circuitry C.

The delay circuitry C of FIG. 1 comprises 34 transistors, 32 of which are configured to switch at every clock edge. This configuration of a large number of series arranged inverter stages results in excessive dynamic power dissipation every clock cycle and occupies a significant circuit area. Thus more power and area efficient delay circuitry is needed. The present invention presents an efficient alternative.

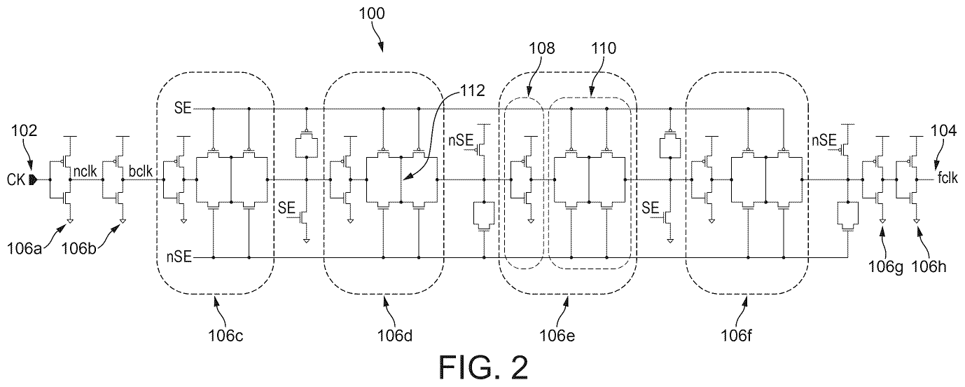

With reference to FIG. 2, there is illustrated delay circuitry 100 according to an approach of present techniques. The delay circuitry 100 comprises an input 102 configured to receive a clock signal, CK, and an output 104 configured to output a delayed clock signal, fclk. The delay circuitry 100 further comprises eight delay stages made up of two inverter stages 106a, 106b, four buffer-inverter units 106c-106f, and two further inverter stages 106g, 106h arranged in series. Inverter 106a outputs an inverted clock signal nclk and inverter 106b outputs a twice inverted clock signal bclk.

Each buffer-inverter unit 106d-106f is configured to receive, buffer and invert an input clock signal and to generate a delayed output clock signal. Each buffer-inverter unit 106d-106f comprises a first logic gate 108 arranged in series with a second logic gate 110. In the circuit shown in FIG. 2, the first logic gate 108 is a clock-controlled gate 108 configured to invert the input clock signal. Switching of the clock-controlled gate 108 is configured to be controlled by the clock signal, CK or a derivative (e.g., an inversion of CK). In this way, the devices of the clock-controlled gate are configured to switch with every clock edge.

In the circuit shown in FIG. 2, the second logic gate 110 is a mode-controlled gate 110 configured to pass the clock signal. Switching of the mode-controlled gate 110 is configured to be controlled by a control signal indicative of a mode of circuit operation. In this way, switching of the mode-controlled gate 110 is independent of the clock signal, CK. In other words, the devices of the mode-controlled gate are configured to switch with every change in mode of circuit operation, and not every clock edge.

In FIG. 2, the mode-controlled gate 110 is a pair of transmission gates and the clock-controlled gate 108 is an inverter. Any suitable gate number, type and pairing may be used. For example, in some implementations, the mode-controlled gate may comprise one transmission gate or more than two transmission gates. In other implementations, the first logic gate may be a mode-controlled gate while the second logic gate may be a clock-controlled gate. Modes of circuit operation may, for example, include a testing mode and a functional, or data operation, mode. The control signal may be, for example, a scan enable signal. In FIG. 2, the scan enable signal is denoted by SE and the inverted scan enable signal by nSE.

By being mode-controlled and independent of the clock signal, the transistors making up the second logic gate 110 may switch very infrequently compared to the transistors of the clock-controlled gate 108, i.e., during data operation, the transmission gates may be always on. Limiting switching activity limits power consumption. So, the static power dissipation of the substantially always-on transistors of the mode-controlled logic gate 110 leads to a low overall power dissipation of the delay circuitry 100 for the delay duration achieved.

For a substantially equivalent duration of delay, the delay circuitry 100 may exhibit a reduction in power dissipation of approximately 14% compared to the clock-controlled inverter delay circuitry C of the prior art, see FIG. 1. A small, around 2%, reduction in area footprint is also achieved.

In some implementations, the link 112 may be removed to provide mode-controlled stacked inverters rather than transmission gates. Using stacked inverters rather than transmission gates may provide additional delay as stacked inverters may generally be slower than transmission gates. As transmission gates generally tend to be faster, their usage could result in less overall delay than stacked inverter topology.

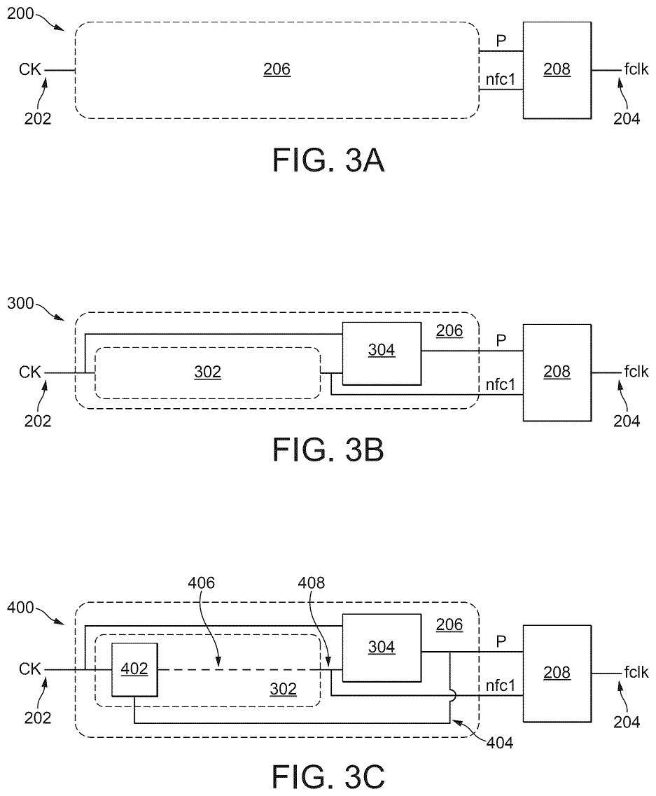

With reference to FIG. 3A-3C, there are illustrated block diagrams of delay circuitry according to an approach of present techniques.

FIG. 3A illustrates delay circuitry 200 comprising an input 202 configured to receive a clock edge, CK, and an output 204 configured to output a delayed clock edge, fclk. The delay circuitry 200 further comprises a pulse generator 206 and a clock output element (or signal output element) 208. The pulse generator 206 is configured to generate a pulse, P, responsive to receiving the input clock edge, CK. The pulse generator 206 is also configured to buffer and invert the input clock edge, CK, to generate a buffered and inverted clock edge, nfc1. The clock output element 208 is configured to receive the pulse, P, and the buffered and inverted clock edge, nfc1, from the pulse generator 206 and further configured to generate a delayed clock edge, fclk, responsive to a trailing edge of the pulse, P, and based on the buffered and inverted clock edge, nfc1.

FIG. 3B illustrates delay circuitry 300. Delay circuitry 300 comprises all the features of delay circuitry 200 which are labelled with like reference numerals and not described again. In FIG. 3B, the pulse generator 206 comprises a delay element 302 and a pulse output element 304. The delay element 302 is configured to receive the input clock edge, CK, and generate the buffered and inverted clock edge, nfc1. The pulse output element 304 is configured to receive the input clock edge CK and the buffered and inverted clock edge, nfc1, and generate the pulse, P.

The pulse output element 304 of FIG. 3B comprises logic, e.g., a logic gate, configured to switch, responsive to receiving the input clock edge, CK, to trigger a start of the pulse, P. The logic is further configured to switch, responsive to receiving the buffered and inverted clock edge, nfc1, to trigger an end of the pulse, P. In this way, a delay effect provided by the delay circuitry 300 corresponds to a duration of switching the delay element 302, a duration of switching the pulse output element 304 and a duration of switching the clock output element 208 sequentially.

FIG. 3C illustrates delay circuitry 400. Delay circuitry 400 comprises all the features of delay circuitry 300 and delay circuitry 200 which are labelled with like reference numerals and not described again. In FIG. 3C, the delay element 302 comprises a combinatorial logic element 402 configured to receive the input clock edge, CK, and at least one other signal.

In FIG. 3C, feedback path 404 is arranged to connect an output of the pulse output element 304 to an input of the combinatorial logic element 402. In this way, the at least one other signal that the combinatorial logic element 402 is configured to receive is the pulse, P. Accordingly, after receiving the pulse, P, the delay element 302 is configured to output a buffered and inverted clock edge, nfc1.

As such, in FIG. 3C, the logic of the pulse output element 304 is configured to switch, responsive to receiving the input clock edge, CK, to trigger a start of the pulse, P. The logic is further configured to switch, responsive to receiving the buffered and inverted clock edge, nfc1, to trigger an end of the pulse. In this way, a delay effect provided by the delay circuitry 400 corresponds to a duration of switching the pulse output element a first time, a duration of switching the delay element, a duration of switching the pulse output element a second time and a duration of switching the clock output element sequentially.

In FIG. 3C, the delay element 302 may comprise further logic, indicated by dashed line 406. The further logic 406 may buffer signals output by the combinatorial logic element 402, for example the further logic 406 may comprise inverters. Any odd number of inverting elements (e.g., combinatorial logic element 402 and further logic 406) may be provided in the delay element such that a buffered and inverted clock edge, nfc1, is delivered at the output of the delay element 408.

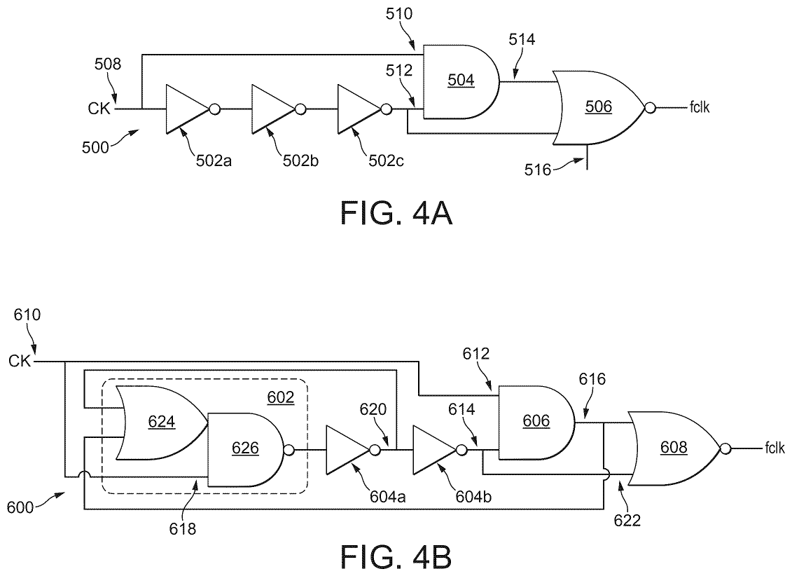

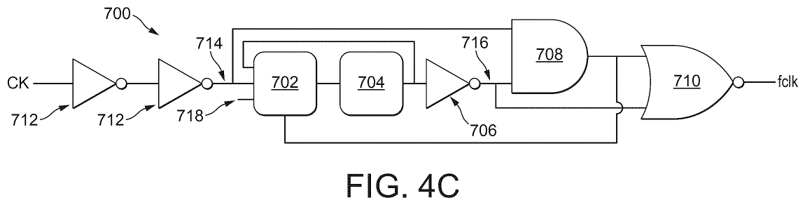

With reference to FIGS. 4A-4C, there are illustrated logic diagrams of delay circuitry according to an approach of present techniques.

FIG. 4A illustrates delay circuitry 500 which shows a specific embodiment of the delay circuitry 200, 300 shown in the block diagrams of FIGS. 3A and 3B. In the delay circuitry 500 of FIG. 4A, the pulse generator is provided by a delay element comprising three inverters 502a, 502b, 502c arranged in series and a pulse output element comprising an AND gate 504. The clock output element (or signal output element) is provided by a NOR gate 506.

In use, when a rising clock edge, CK, arrives at the input 508, it is substantially instantaneously received at the first input 510 to the AND gate 504 and the input to the first inverter of the delay element 502a. Having previously buffered and inverted a falling clock edge, the output of the delay elements 502a, 502b, 502c, and therefore the second input 512 of the AND gate 504, is already 1, so the arriving rising clock edge causes the AND gate 504 to output a 1 at 514, this is the start of the pulse. Consequently, the inputs to NOR gate 506 are both 1 and the output does not switch from 0.

Simultaneously, the rising clock edge is propagating through the inverters 502a, 502b, 502c of the delay element. The inverters 502 a, 502 b, 502 c buffer the clock edge such that it arrives at the second input 512 of the AND gate 504 after a delay. When it arrives at the second input 512 of the AND gate 504 it is inverted compared with the clock edge, CK, so is 0. Hence, the AND gate 504 switches back to 0. This is the end of the pulse.

At this point, the inputs to the NOR gate 506 are both 0, so the NOR gate switches to output a 1, finally outputting the delayed clock edge, fclk. In this way, the delay effect corresponds to a duration of switching the inverters 502a, 502b, 502c of the delay element, a duration of switching the AND gate 504 and a duration of switching the NOR gate 506 sequentially as that is the critical data path. The first switching of the AND gate takes place at the same time as the clock edge is propagating through the inverters 502a, 502b, 502c of the delay element and is therefore not on the critical data path.

In FIG. 4A, NOR gate 506 is a three input NOR gate configured to receive the output of the AND gate 504, the output of the delay elements 502a, 502b, 502c and a control signal 516. The control signal 506 is optional and may be used to switch a mode of circuit operation.

FIG. 4B illustrates delay circuitry 600 which shows a specific embodiment of the delay circuitry 400 shown in the block diagram of FIG. 3C. In the delay circuitry 600 of FIG. 4B, the delay element of the pulse generator comprises a combinatorial logic element 602 and two inverters 604a, 604b arranged in series. In FIG. 4B, the combinatorial logic element 602 is an OR-AND-invert (or OR-NAND) gate. The pulse output element comprises an AND gate 606. The clock output element (or signal output element) is provided by a NOR gate 608.

In use, when a rising clock edge, CK, arrives at the input 610, it is substantially instantaneously received at the first input 612 to the AND gate 606 and the input to the NAND gate 626 of the OR-NAND gate 602. Having previously seen a buffered and inverted a falling clock edge, the output of the delay elements 602, 604a, 604b, and therefore the second input 614 of the AND gate 606, is already 1, so the arriving rising clock edge causes the AND gate 606 to output a 1 at 616, this is the start of the pulse. Consequently, the inputs to NOR gate 608 are both 1 and the output does not switch from 0.

Simultaneously, the rising clock edge is received at the input 618 to the NAND gate 626 of the OR-NAND gate 602. Initially, the inputs to the OR gate 624 of the OR-NAND gate 602 are both 0 because, while the clock, CK, was 0, the output of the AND gate 606 was 0 and the twice inverted output 620 was also 0. Therefore, on receiving the rising clock edge, the output of the OR-NAND gate 602 does not switch from 1.

After the rising clock edge has caused the AND gate 606 to generate the pulse, that pulse is received at the OR-NAND gate 602. On receipt of the pulse, the output of the OR-NAND gate 602 switches to 0. That signal is inverted by inverters 604a and 604b in turn such that a buffered and inverted clock edge, a 0, is received at 614.

The buffered and inverted clock edge, a 0, is received at the second input 614 to AND gate 606. Hence, the AND gate 504 switches back to 0. This is the end of the pulse.

At this point, the inputs to the NOR gate 608 are both 0, so the NOR gate switches to output a 1, finally outputting the delayed clock edge, fclk. In this way, the delay effect corresponds to a duration of switching the AND gate 606 a first time, a duration of switching the OR-NAND gate 602 and the inverters 604a, 604b, a duration of switching the AND gate 606 a second time and a duration of switching the NOR gate 608 sequentially as that is the critical data path. The first switching of the AND gate takes place to generate the pulse and the OR-NAND gate does not switch until the pulse is received so the delay effect of the AND gate 606 is used twice in the circuitry of FIG. 4B. In this way, the delay effect of the circuit of FIG. 4b is enhanced by provision of the feedback path that passes the pulse through the delay element. Alternative configurations of delay elements and logic gates are possible.

When a falling clock edge, CK, arrives at the input 610, it is substantially instantaneously received at the input to the NAND gate 626 of the OR-NAND gate 602, consequently the OR-NAND gate switches to output a 1. Contemporaneously, the AND gate 606 also receives the falling clock edge and does not switch. Next, the clock edge is inverted by inverters 604a, 604b such that the output of the delay element, and therefore the second input 622 of the NOR gate 608, is 1. Consequently, the NOR gate 608 switches to output 0. Therefore, on a falling clock edge, the delay effect is limited to corresponding to a duration of switching the delay element (OR-NAND 602, and inverters 604a, 604b) and a duration of switching the NOR gate 608 sequentially only. No pulse is generated by a falling input clock edge.

The delay circuitry of FIG. 4B uses a pulse generator to allow the AND stage to be used twice to increase the delay provided for a given number of stages, i.e., a power dissipation and area requirement is reduced for a given delay. The NOR gate is provided to reconstitute a substantially 50% duty cycle from the pulse and the buffered and inverted clock edge such that the delayed clock signal is suitable for a use in a flip flop. In this way, the NOR gate generates a delayed clock signal having a duty cycle that is substantially identical to a duty cycle of the input clock signal.

FIG. 4C illustrates delay circuitry 700 which shows an alternative specific embodiment of the delay circuitry 400 shown in the block diagram of FIG. 3C. In the delay circuitry 700 of FIG. 4C, the delay element of the pulse generator comprises a combinatorial logic element 702, a buffer-inverter unit 704 and an inverter 706 arranged in series. The pulse output element comprises an AND gate 708. The clock output element (or signal output element) is provided by a NOR gate 710.

In FIG. 4C, the combinatorial logic element 702 is a four input OR-AND-invert (or OR-NAND) gate, that is, a three input OR gate feeding into a two input NAND gate. The OR-NAND gate 702 is similar to the OR-NAND gate 602 of FIG. 4B. In FIG. 4C, the OR-NAND gate 702 is simplified for clarity. The four input OR-NAND 702 has one additional input 718 compared to the OR-NAND 602 of FIG. 4B. The additional input 718 is a control signal used to switch a mode of circuit operation.

The buffer-inverter unit 704 is configured to buffer and invert the clock edge. The buffer-inverter unit 704 may comprise the circuitry of a buffer-inverter unit of FIG. 2, e.g., buffer-inverter unit 106c, i.e., a transmission gate stage and an inverter stage. Any suitable number of transmission gates may be used. Alternatively, stacked inverters may be used. Transmission gate or stacked inverters may be used to enhance delay effect while minimising a number of devices configured to switch at each clock edge.

FIG. 4C further comprises two inverters 712 arranged in series upstream of the OR-NAND gate 702. Any even number of inverters, or other inverting elements, may be provided to buffer the clock edge before it reaches the input 714 to the pulse generator such that a buffered, but not inverted, clock edge is received at the input 714. Any odd number of inverting elements (e.g., OR-NAND gate, buffer-inverter unit, inverter) may be provided in the delay element such that a buffered and inverted clock edge is delivered at the output of the delay element 716, corresponding to nfc1 in FIGS. 3A-C.

In use, the circuit of FIG. 4C operates a similar way to the circuit of FIG. 4B, with additional buffering of the clock edge by inverter 712 at the input. The delay circuitry of FIGS. 4B and 4c both use a pulse generator to allow the AND stage to be used twice to increase the delay provided for a given number of stages, i.e., a power dissipation and area requirement is reduced for a given delay. The buffer-inverter unit 704 of FIG. 4C is provided to enhance a delay effect for a given power dissipation and area footprint.

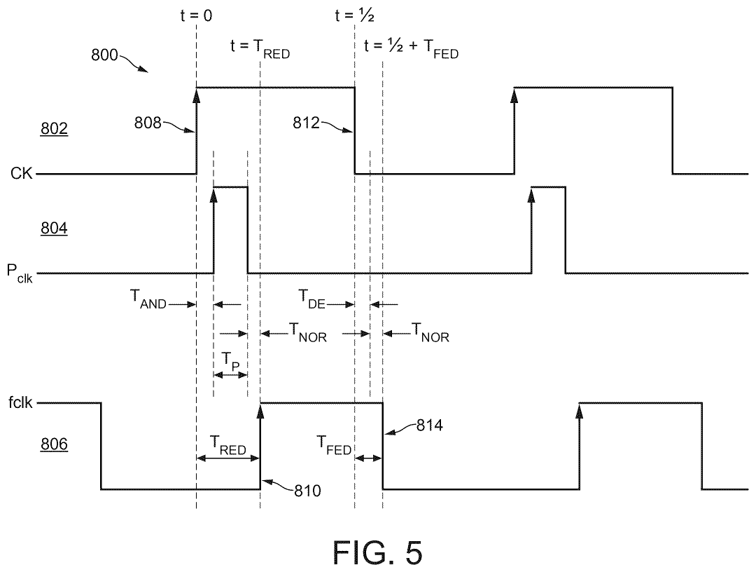

FIG. 5 provides a schematic timing diagram 800 illustrating timing characteristics of the delay circuitry 600 of FIG. 4B. The timing diagram 800 includes a voltage waveform 802 corresponding to input clock, CK, a voltage waveform 804 corresponding to the pulse, P_{clk}, and a voltage waveform 806 corresponding to the delayed clock, fclk.

The rising edge 808 of the input clock waveform 802 arrives first, at t=0. After a delay corresponding to a duration of switching the AND gate 606 in FIG. 4B, T_{AND}, the pulse is triggered. The duration of the pulse corresponds to the duration of switching the components of the pulse generator, i.e., the OR-NAND gate 602, the inverters 604a, 604b and AND gate 606 (for a second time) of FIG. 4B. The duration of the pulse is labelled T_{P} in FIG. 5. Once the pulse has elapsed, i.e., the trailing edge of the pulse is received at the NOR gate 608 of FIG. 4B, the NOR gate 608 switches, incurring a delay labelled T_{NOR}. After T_{NOR}, the delayed clock edge 810 is output by the NOR gate 608 of FIG. 4B at t=T_{RED}.

The total delay, T_{RED}, between the rising clock edge 808 of waveform 802 and the delayed rising clock edge 810 of waveform 806 is the sum of T_{AND}, T_{P} and T_{NOR}; corresponding to a duration of switching the AND gate 606, a duration of the pulse and a duration of switching the NOR gate 608 sequentially.

The falling edge 812 of the input clock waveform 802 arrives after half a clock period, at t=½. After a delay corresponding to a duration of switching the delay element (OR-NAND 602, and inverters 604a, 604b) in FIG. 4B, T_{DE}, a 1 is delivered to one input of the NOR gate 608, causing the NOR gate 608 of FIG. 4B to switch, incurring a delay of T_{NOR}. After T_{NOR}, the delayed clock edge 814 is output by the NOR gate 608 of FIG. 4B at t=½+T_{FED}.

The total delay, T_{FED}, between the falling clock edge 812 of waveform 802 and the delayed falling clock edge 814 of waveform 806 is the sum of T_{DE} and T_{NOR}; corresponding to a duration of switching the delay element (OR-NAND 602, and inverters 604a, 604b) and a duration of switching the NOR gate 608 sequentially.

The duration of T_{FED} is slightly shorter than the duration of T_{RED} due to the action of the pulse in the rising edge delay path that is absent in the falling edge delay path. This leads to a duty cycle in the delayed clock, fclk, of slightly less than 50%. In this way, the NOR gate generates a delayed clock signal having a duty cycle that is substantially identical to a duty cycle of the input clock signal.

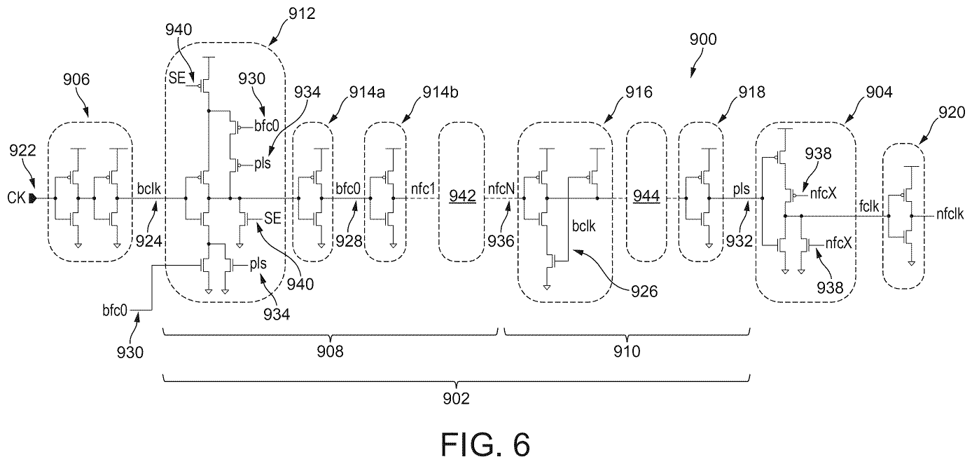

FIG. 6 illustrates a transistor level implementation of delay circuitry 900 according to an implementation of present techniques. FIG. 6 shows the delay circuitry 900 comprising a pulse generator 902 and a clock output element (or signal output element) 904. The delay circuitry 900 corresponds largely to delay circuitry 600 of FIG. 4B except using a four input OR-NAND gate and having two additional inverters 906 arranged in series with, and upstream of, the pulse generator 902, as in the delay circuitry of FIG. 4C.

The pulse generator comprises a delay element 908 and a pulse output element 910. The delay element comprises a combinatorial logic element 912 and two inverters 914a, 914b. The delay element 908 may also comprise a further N stages of inverter pairs 942. N may be selected to provide a delay effect appropriate for the application of the delay circuitry 900. The output of inverter 914b is nfc1 and the output of the N stages of inverter pairs 942 is nfcN, intermediate signals may be named in a corresponding manner. A general name for the output 936 of the delay element 908 may be nfcX, which may be any one of nfc1-nfcN.

The combinatorial logic element 912 is an OR-NAND gate 912. The pulse output element 910 comprises an AND gate 910 formed of a NAND gate 916 and an inverter 918. The pulse output element 910 may also comprise a further M stages of inverter pairs 944. M may be selected to provide a delay effect appropriate for the application of the delay circuitry 900. Additional inverter pairs included at 944 may provide a highly power-efficient and area-efficient additional delay effect as the delay effect of circuitry 900 includes two instances of the delay effect of the pulse output element 910; that is, the delay effect of AND gate 910 is used twice, as discussed above in relation AND gate 606 and 708 of FIGS. 4B and 4C respectively.

The clock output element 904 comprises a NOR gate 904 configured to output the delayed clock signal, fclk. A further inverter 920 is provided downstream of the NOR gate 904 to provide the logical complement of the delayed clock output, nfclk.

At input 922, the input clock edge, CK, is received. After inverters 906, a buffered clock edge, bclk, is output at 924. As well as being connected to the input of OR-NAND gate 912, the output 924 of inverters 906, bclk, is connected to input 926 of NAND gate 916. The output 928 of inverter 914a, a further buffered clock edge, bfc0, is fed back to inputs 930 of OR-NAND gate 912. Additionally, the output 932 of AND gate 910, the pulse signal, pls, is fed back to inputs 934 of OR-NAND gate 912. Finally, the output 936 of the delay element 908, a buffered and inverted clock edge, nfcX (i.e., any of nfc1-nfcN), is fed forward to inputs 938 of NOR gate 904. NOR gate 904 outputs the delayed clock edge, fclk, and inverter 920 outputs an inverted delayed clock edge nfclk.

Optionally, OR-NAND gate 912 may comprise a fourth input, as shown at 940 in FIG. 6, configured to receive a control signal, SE. An inverted control signal, nSE, may alternatively be supplied at the clock output element 904, and the NOR gate 904 modified accordingly. For example, source terminals of the two N-channel transistors of NOR gate 904 may be coupled to a drain terminal of an additional N-channel transistor whose gate terminal is coupled to nSE and source terminal coupled to a low supply, e.g., ground. Further, an additional P-channel transistor may be coupled between a high supply and the fclk node with the gate terminal coupled to nSE. The control signal may be used to adjust a mode of operation of the delay circuit. Modes of circuit operation may, for example, include a testing mode and a functional, or data operation, mode. The control signal may be, for example, a scan enable signal.

The delay circuitry of FIG. 6 may offer a significant power and area saving over the prior art.

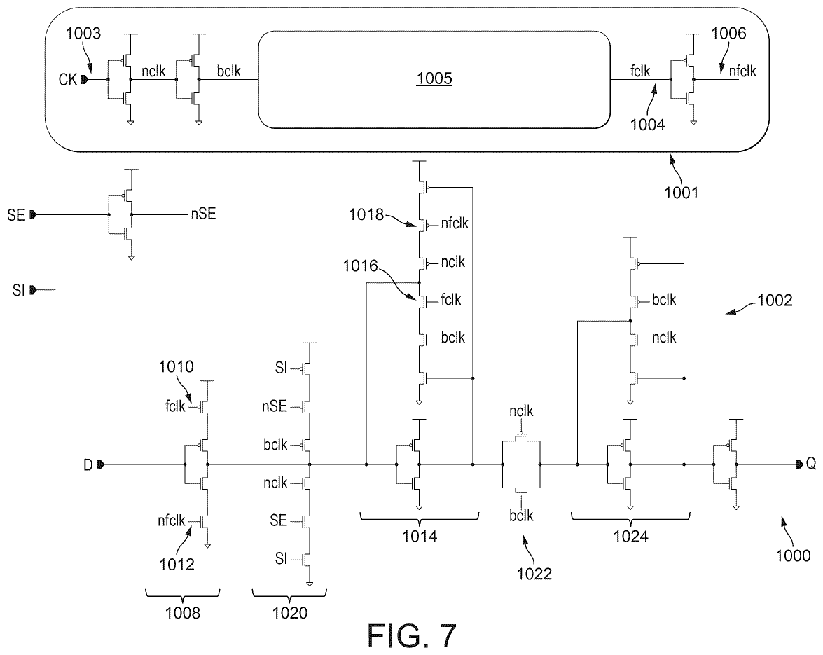

FIG. 7 illustrates a transistor level implementation of an apparatus 1000 according to an approach of present techniques. The apparatus 1000 is a soft-edge flip flop. The apparatus 1000 comprises delay circuitry 1001, e.g., corresponding to delay circuitry 900 of FIG. 6, and a flip flop 1002. The delay circuitry 1001 receives an input clock edge, CK, at 1003 and generates a delayed clock signal, fclk, at 1004 and a logical complement of that delayed clock signal, nfclk, at 1006. The delay circuitry 1001 may comprise any suitable delay circuitry described herein. For simplicity, specifics of the delay circuitry 1001 are omitted from FIG. 7 and indicated only by block 1005.

The delayed clock signal, fclk, is provided to the flip flop in data multiplexer 1008 at 1010. The inverted delayed clock signal, nfclk, is provided to the flip flop in data multiplexer 1008 at 1012.

The delayed clock signal, fclk, is also provided to the flip flop 1002 in the storage feedback loop 1014 of the master latch at 1016. The inverted delayed clock signal, nfclk, is also provided to the flip flop 1002 in the storage feedback loop 1014 of the master latch at 1018. The inverted and twice inverted clock signals, nclk and bclk respectively, are provided to the flip flop 1002 in the scan multiplexer 1020, the storage feedback loop 1014 of the master latch, the transmission gate 1022 and the storage feedback loop 1024 of the slave latch. Scan enable, SE, and its inversion, nSE, as well as test input SI, are also provided to the flip flop 1002 in the scan multiplexer 1020.

1. Delay circuitry comprising:
a pulse generator to generate a pulse responsive to receiving an input signal edge and to buffer and invert the input signal edge to generate a buffered and inverted signal edge; and
a signal output element to receive the pulse and the buffered and inverted signal edge from the pulse generator and to generate a delayed signal edge responsive to a trailing edge of the pulse and based on the buffered and inverted signal edge.

2. The delay circuitry of claim 1, wherein the pulse generator comprises:
a delay element to receive the input signal edge and generate the buffered and inverted signal edge; and
a pulse output element to receive the input signal edge and the buffered and inverted signal edge and generate the pulse.

3. The delay circuitry of claim 2, wherein the pulse output element comprises logic to:
switch, responsive to receiving the input signal edge, to trigger a leading edge of the pulse; and
switch, responsive to receiving the buffered and inverted signal edge, to trigger a trailing edge of the pulse;
to provide a delay effect corresponding to a duration of switching the delay element, switching the pulse output element and switching the signal output element sequentially.

4. The delay circuitry of claim 2, wherein the pulse output element comprises an AND gate and the signal output element comprises a NOR gate; or wherein the pulse output element comprises an OR gate and the signal output element comprises a NAND gate.

5. The delay circuitry of claim 2, wherein the delay element comprises a logic inverting element to buffer and invert the input signal edge.

6. The delay circuitry of claim 2, wherein the delay element further comprises a transmission gate.

7. The delay circuitry of claim 2, wherein the delay element comprises a combinatorial logic element to receive the input signal edge and at least one other signal.

8. The delay circuitry of claim 7, wherein the combinatorial logic element comprises an OR-AND-invert gate or an AND-OR-invert gate.

9. The delay circuitry of claim 7, wherein the combinatorial logic element of the delay element is configured to receive a partially buffered signal edge.

10. The delay circuitry of claim 7, wherein the combinatorial logic element of the delay element is configured to receive a control signal to adjust a mode of operation of the delay circuitry.

11. The delay circuitry of claim 7, wherein the combinatorial logic element of the delay element is configured to receive the pulse via a feedback path arranged to connect an output of the pulse output element to an input of the combinatorial logic element; and
wherein the delay element is configured to output the buffered and inverted signal edge responsive to receiving the pulse.

12. The delay circuitry of claim 11, wherein the pulse output element comprises logic to:
switch, responsive to receiving the input signal edge, to trigger a leading edge of the pulse; and
switch, responsive to receiving the buffered and inverted signal edge, to trigger a trailing edge of the pulse;
to provide a delay effect corresponding to a duration of switching the pulse output element a first time, switching the delay element, switching the pulse output element a second time and switching the signal output element sequentially.

13. The delay circuitry of claim 1, wherein the input signal edge is an input clock edge.

14. The delay circuitry of claim 1, wherein the signal output element is configured to generate a delayed signal having a duty cycle that is substantially identical to a duty cycle of the input signal.

15. The delay circuitry of claim 1, wherein the signal output element is configured to receive a control signal to adjust a mode of operation of the delay circuitry.

16. Delay circuitry comprising:
a buffer-inverter unit to receive, buffer and invert an input signal and to generate a delayed output signal, the buffer-inverter unit comprising a first logic gate arranged in series with a second logic gate;
wherein one of the first logic gate and the second logic gate is a signal-controlled gate configured to invert the input signal and the other of the first logic gate and the second logic gate is a mode-controlled gate configured to pass the input signal;
wherein switching of the signal-controlled gate is configured to be controlled by the input signal; and
wherein switching of the mode-controlled gate is configured to be controlled by a control signal indicative of a mode of circuit operation such that switching of the mode-controlled gate is independent of the input signal.

17. The delay circuitry of claim 16, wherein the mode-controlled gate comprises a plurality of mode-controlled gate stages arranged in series.

18. An apparatus comprising the delay circuitry of claim 1 and a flip flop to store a data signal responsive to receiving the delayed signal edge from the delay circuitry.

19. An apparatus comprising the delay circuitry of claim 16 and a flip flop to store a data signal responsive to receiving the delayed signal edge from the delay circuitry.

20. Delay circuitry comprising:
a pulse generator to generate a pulse responsive to receiving an input signal edge and to buffer and invert the input signal edge to generate a buffered and inverted signal edge; and
a signal output element to receive the pulse and the buffered and inverted signal edge from the pulse generator and to generate a delayed signal edge responsive to a trailing edge of the pulse and based on the buffered and inverted signal edge;
the pulse generator comprising:
a buffer-inverter unit to receive, buffer and invert an input signal and to generate a delayed output signal, the buffer-inverter unit comprising a first logic gate arranged in series with a second logic gate;
one of the first logic gate and the second logic gate being a signal-controlled gate to invert the input signal and the other of the first logic gate and the second logic gate being a mode-controlled gate to pass the input signal;
wherein switching of the signal-controlled gate is configured to be controlled by the input signal; and
wherein switching of the mode-controlled gate is configured to be controlled by a control signal indicative of a mode of circuit operation such that switching of the mode-controlled gate is independent of the input signal.
